(19) United States
(12) Patent Application Publication
(10) Pub. No.: US 2025/0314730 A1
(43) Pub. Date: Oct. 9, 2025

(54) Magnetic Resonance Data Determination with Spectral Selection

(71) Applicant: Siemens Healthineers AG, Forchheim (DE)

(72) Inventor: Thorsten Feiweier, Poxdorf (DE)

(73) Assignee: Siemens Healthineers AG, Forchheim (DE)

(21) Appl. No.: 19/174,140

(22) Filed: Apr. 9, 2025

(30) Foreign Application Priority Data
Apr. 9, 2024 (DE) 10 2024 203 206.9

(51) Int. Cl. G01R 33/565; G01R 33/54; G01R 33/561

(52) U.S. Cl. CPC G01R 33/56527; G01R 33/543; G01R 33/5615; G01R 33/56554

(57) ABSTRACT

A method for recording scan data of an examination object which includes spins of at least two different spin species by means of a magnetic resonance system. The method includes: radiating in a composite RF pulse, for example, a binomial pulse comprising at least two subpulses; switching bipolar slice selection gradients so that successive subpulses of the composite RF pulse are encoded with differently polarized slice selection gradients; recording as scan data magnetic resonance signals triggered by the composite RF pulse; and storing and/or further processing the recorded scan data, wherein the subpulses are radiated in at a frequency that is detuned by a detuning shift relative to a resonance frequency of a spin species that is to be represented, such that by way of the detuning shift a linear evolution of the phase over the temporal progression of the composite RF pulse results.

### TECHNICAL FIELD

The disclosure relates to an improved determination of magnetic resonance data with spectral selection.

### BACKGROUND

Magnetic resonance technology (hereinafter, the abbreviation MR stands for magnetic resonance) is a known technology with which images of the interior of an examination object can be generated. Expressed simply, for this purpose, the examination object is positioned in a magnetic resonance device in a relatively strong, static, homogeneous main magnetic field, also known as the B0 field, with field strengths from 0.2 tesla to 7 tesla or more, so that its nuclear spins become oriented along the main magnetic field. In order to trigger nuclear spin resonances that are measurable as signals, high frequency excitation pulses (RF pulses) are radiated into the examination object and the nuclear spin resonances produced are measured as so-called k-space data by means of coils configured for receiving and, on the basis thereof, MR images are reconstructed or spectroscopic data is established. The alternating magnetic field created by the excitation pulse radiated in by way of the at least one transmitting coil is also known as the B1-field. For position encoding of the measurement data, rapidly switched magnetic gradient fields, known as gradients for short, are overlaid on the main magnetic field. A scheme that is used which defines a temporal sequence of RF pulses to be radiated in and gradients to be switched is known as a pulse sequence (scheme) or sequence for short. The recorded scan data is digitized and stored as complex number values in a k-space matrix. From the k-space matrix populated with values, an associated MR image can be reconstructed, for example, by means of a multi-dimensional Fourier transform.

Protons in the different (chemical) environments are denoted as different spin species. Different environments of protons shield the B0 field to different extents so that a different magnetic field arises at a nucleus that leads to different resonance frequencies. What is referred to here is a chemical shift between the different spin species. This can lead, during the signal recording, to different phase angles of the acquired signals provided no specific countermeasures are implemented. The most prominent representatives of different spin species in (animal or human) patients as examination objects are, firstly, fat and, secondly, water, although applications for other spin species, for example, silicone, are also possible. The resonance frequency of protons bound to lipid molecules, which are allocated to the spin species “fat,” is approximately 3.3-3.5 ppm lower than the resonance frequency of protons bound to water, which are allocated to the spin species “water”.

This fact can be utilized to suppress the fat signal with frequency-selective RF saturation of RF inversion pulses that are switched before a subsequent signal recording, for example, by means of a multi-echo recording technique. A disadvantage of such a fat suppression technique with frequency-selective RF saturation pulses or RF inversion pulses is that the suppression pulses that are needed require additional time in the progression of the sequence, that they increase the applied specific absorption rate (SAR) and always act upon the entire imaging volume and thus, for example, cannot be optimized for a current slice.

A targeted excitation and/or suppression of signal contributions from spin species with a particular chemical shift has a high level of relevance in MR imaging. For example, for particular clinical investigations, exclusive representation of the water signal can be of interest—and cases are also imaginable in which exclusively fat-bound protons (or those in other chemical compounds, for example, silicone) are to be mapped.

There are also imaging techniques in which a spectrum of spin species with different chemical shifts would lead to undesirable image artifacts, and for this reason, a spectral selection is wanted. This includes, for example, echo-planar imaging (EPI), a multi-echo recording technique in which, due to the immanent low pixel bandwidth along the phase-encoding direction, spin species with different precession frequencies are represented spatially displaced in the image, wherein the shifts can amount to several millimeters. Partial images of the individual spin species become overlaid, due to the shift, and interfere with one another so that a diagnosis based upon the MR images obtained is made significantly more difficult for medical personnel observing them. This is clinically relevant, in particular, for example, in diffusion-weighted imaging in which EPI techniques are normally used.

As an alternative to a (simple) spectral saturation or inversion mentioned above, for a spectral selection of the mapped spin species (for two-dimensional or even three-dimensional recording techniques), so-called composite RF pulses which consist of at least two successive (concatenated) RF pulses, also referred to as subpulses of the composite RF pulses, can be used. The expression “composite” indicates that the subpulses are not emitted in isolation but are composited or combined in such a way that the resultant signal is optimally influenced for a particular imaging goal, for example, a frequency selectivity. Thus the composite RF pulse emulates the effect of a simple RF pulse, but has a built-in compensation mechanism which, although it possibly makes it marginally longer than a conventional RF pulse, nevertheless allows the omission of an otherwise necessary use of additional pulses to suppress undesirable signals, so that the applied SAR is simultaneously reduced, and slice-specific optimizations are made possible.

If composite RF pulses are used for a frequency selection for exciting the spin species water, this is referred to as a “water excitation”. For a water excitation of this type, composite RF pulses referred to as binomial pulses are used, in which the relative flip angles of the subpulses are coefficients of a binomial series (for example, 1-1, 1-2-1, 1-3-3-1, etc.). A desired spectral selectivity can be created across a temporal spacing ΔT between the subpulses, as described, for example, in the article by P. J. Hore, “A new method for water suppression in the proton NMR spectra of aqueous solutions”, J. Magn. Reson. 54: pp. 539-542, 1983.

Known spatially selective and spectrally selective water excitations comprise, for example, a water excitation with unipolar slice selection gradients. FIG. 1 shows, by way of example, a schematic representation of a portion of a pulse sequence scheme for a unipolar 1-3-3-1 binomial as a composite RF pulse RF1. In the top line RF, RF pulses to be radiated in and, in the bottom line, G_{S} slice selection gradients to be switched (without ramps) are shown. The excitation scheme consists herein of four successive slice-selection subpulses RF* with an amplitude ratio of 1:3:3:1 so that when, for example, a flip angle of 90° is to be generated with the composite RF pulse, the subpulses RF* have flip angles of 11.25°, 33.75°, 33.75° and 11.25°, respectively. All four subpulses RF* are radiated in with the same phase and synchronously with the spin species to be excited (i.e., at exactly the resonance frequency of the spin species to be excited, for example, water). In the middle line PhN, by way of example, a possible creation of the same phases of the subpulses by applying a constant phase by means of the use of a numerically controlled oscillator (NCO) is shown.

In a unipolar slice selection shown in FIG. 1, during each subpulse RF*, a slice selection gradient is switched, in each case, with the same polarity (for example, herein, positive). For rephasing, in each case, a gradient with inverted polarity in the slice selection direction is switched between the subpulses RF*. As a result, however, only a short time TRF, which is significantly shorter than the temporal spacing ΔT of the subpulses RF*, is available as the maximum pulse duration for the respective emission of the subpulses RF*. A consequence of the short pulse duration TRF available for the subpulses RF* is, for example, a reduced quality of the achievable slice profile, since the subpulses RF* can only be applied with a small bandwidth time product (BWT). Secondly, the available pulse duration TRF limits the minimum achievable slice thickness (and therewith the possible clinical applications) since at least the central half-wave must be applied with a duration suited to the slice thickness.

An advantage of the use of a unipolar slice selection of this type in conjunction with binomial pulses is that the spatial slice profiles of the spins manipulated by way of the respective subpulses RF* match for all subpulses RF* so that the desired binomial amplitude ratio of the subpulses RF* (here, for example, 1-3-3-1) remains assured for each spatial position within the slice profile.

Spatially selective and spectrally selective water excitations with bipolar slice selection gradients are also known. FIG. 2 shows, by way of example, a schematic representation of a portion of a pulse sequence scheme for a variant of a 1-3-3-1 binomial pulse as a composite RF pulse RF1 with a bipolar slice selection. Similarly to FIG. 1, in FIG. 2, in the top line RF, RF pulses to be radiated in and, in the bottom line, G_{S} slice selection gradients to be switched (without ramps) are shown. The excitation scheme consists herein (as in FIG. 1) of four successive slice-selection subpulses RF* with an amplitude ratio of 1:3:3:1. All four subpulses RF* are radiated in with the same phase and synchronously with the spin species to be excited (i.e. at exactly the resonance frequency of the spin species to be excited, for example, water). In the middle line PhN, by way of example, a possible creation of the same phases of the subpulses by applying a constant phase by means of the use of a numerically controlled oscillator (NCO) is shown.

In a bipolar slice selection, shown in FIG. 2, during the successive subpulses RF′, a slice selection gradient is switched alternatingly, in each case, with a different polarity (for example, herein, positive-negative-positive-negative). In this way, a time TRF is available for the respective emission of the subpulses RF′ as the maximum pulse duration, which can now assume the entire temporal spacing ΔT of the subpulses RF′, which in comparison with the unipolar variant, increases the quality of an achievable slice profile and also permits an excitation of thinner slices.

However, through the use of slice selection gradients having different polarity, in conjunction with the different precession frequencies for the different spin species, due to the chemical shift, for the non-resonant spin species that are to be suppressed, for example, fat, a spatial shift of the slice profiles of the subpulses RF′ encoded with positive polarity (for example, herein, the first and the third) as compared with the slice profiles of the subpulses RF′ encoded with negative polarity (for example, herein, the second and the fourth), is generated. Particularly in edge regions of the desired slice to be manipulated with the binomial pulse, this leads to a deviation from the desired amplitude ratio of the binomial pulse, so that the desired spectral selection does not take place fully, but rather a residue of the magnetization of the unwanted spin species, for example, of fat, remains and is also scanned as a signal. A contamination of this type with signal from the unwanted spin species has a negative effect on the image quality achievable.

The spatially selective composite RF pulses described in the prior art, for example, binomial pulses, therefore have restrictions: in some methods, the spectral selectivity is restricted, whereas other methods have limitations regarding the quality of slice profiles and/or the minimum slice thicknesses that can be realized.

### SUMMARY

It is, therefore, an object of the disclosure to avoid the aforementioned disadvantages and to enable a high degree of a selection of a spin species with simultaneously good achievable quality and small thickness of the slice profiles achieved.

This object is achieved by a method for recording scan data of an examination object which comprises spins of at least two different spin species, by means of a magnetic resonance system according to claim 1, a magnetic resonance system according to claim 15, a computer program according to claim 16 and an electronically readable data carrier according to claim 17.

A method according to the disclosure for recording scan data of an examination object which comprises spins of at least two different spin species by means of a magnetic resonance system comprises the steps:
radiating in a composite RF pulse, for example, a binomial pulse comprising at least two subpulses with a predetermined phase offset between successive subpulses,
switching bipolar slice selection gradients so that successive subpulses of the composite RF pulse are encoded with differently polarized slice selection gradients,
recording as scan data magnetic resonance signals triggered by the composite RF pulse,
storing and/or further processing the recorded scan data,
wherein the subpulses are radiated in at a frequency that is detuned by a detuning shift relative to a resonance frequency of a spin species that is to be represented, such that by way of the detuning shift a linear evolution of the phase over the temporal progression of the composite RF pulse results.

By way of the detuning according to the disclosure of the frequency at which subpulses of the composite RF pulse are radiated in, the slices that are manipulated by the subpulses can be adapted in their slice profiles such that both a good spectral selectivity and also a high quality of the achieved spatial selectivity, in particular relative to the achievable slice profiles and their minimum thickness, are achieved.

A magnetic resonance system, according to the disclosure, comprises a magnet unit, a gradient unit, a high frequency unit, and a control facility with a detuning unit, said control facility being configured for carrying out a method according to the disclosure.

A computer program according to the disclosure implements a method according to the disclosure on a control facility when it is executed on the control facility. For example, the computer program comprises commands which, when the program is executed by a control facility, for example, a control facility of a magnetic resonance system, cause said control facility to carry out a method according to the disclosure. The control facility can be constructed in the form of a computer.

Herein, the computer program can also be available in the form of a computer program product which can be loaded directly into a memory store of a control facility, having program code means in order to carry out a method according to the disclosure when the computer program product is executed in a computing unit of the computing system.

A computer-readable storage medium according to the disclosure comprises commands which, when executed by a control facility, for example, a control facility of a magnetic resonance system, cause it to carry out a method according to the disclosure.

The computer-readable storage medium can be configured as an electronically readable data carrier which comprises electronically readable control information stored thereon, which comprises at least one computer program according to the disclosure and is configured such that, when the data carrier is used in a control facility of a magnetic resonance system, it carries out a method according to the disclosure.

The advantages and aspects set out in relation to the method apply accordingly also to the magnetic resonance system, the computer program product, and the electronically readable data carrier.

### DESCRIPTION OF THE DRAWINGS

Further advantages and details of the present disclosure are disclosed in the exemplary aspects described below and by reference to the drawings. The examples given do not represent any restriction of the aspects of the disclosure. In the drawings:

FIG. 1 shows an exemplary, schematic representation of a portion of a pulse sequence scheme for a unipolar 1-3-3-1 binomial pulse as a composite RF pulse from the prior art;

FIG. 2 shows an exemplary, schematic representation of a portion of a pulse sequence scheme for a bipolar 1-3-3-1 binomial pulse as a composite RF pulse from the prior art;

FIG. 3 shows a schematic flow diagram of a method according to the disclosure for recording scan data of an examination object, which comprises spins of at least two different spin species, having improved simultaneous spatial and spectral selection;

FIGS. 4-5 show exemplary, schematic representations of a portion of pulse sequence schemes for possible composite RF pulses according to the disclosure; and

FIG. 6 shows a schematic representation of a magnetic resonance system according to the disclosure.

### DETAILED DESCRIPTION

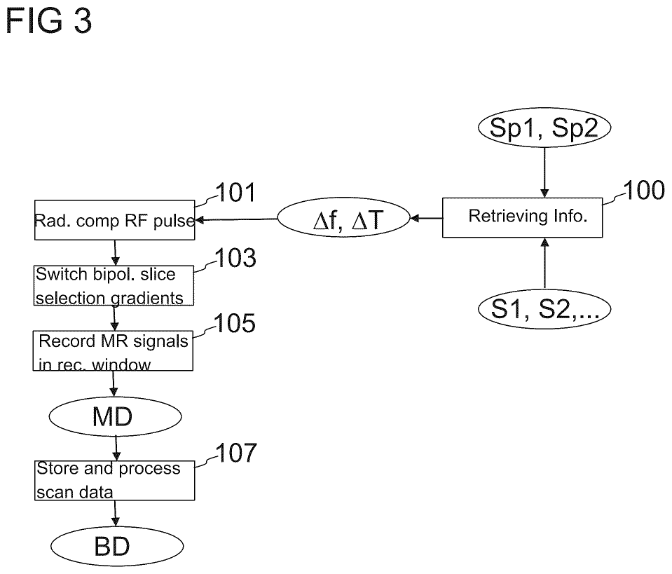

FIG. 3 shows a schematic flow diagram of a method according to the disclosure for recording scan data of an examination object which comprises spins of at least two different spin species Sp1, Sp2 (block 100), by means of a magnetic resonance system. The at least two different spin species can be spin species from the group of spin species water, fat and silicone.

At least one composite RF pulse comprising at least two subpulses with a predetermined phase offset between successive subpulses is radiated into the examination object (block 101). The composite RF pulse can be a binomial pulse. However, other types of composite RF pulses are also conceivable. The phase offset between successive subpulses of the at least two subpulses can be selected such that, for example, a signal contribution from the spin species to be represented is as large as possible compared with signal contributions from other spin species of the at least two spin species. This can be achieved in that, for example, by means of the selected phase offset, a signal contribution from a spin species to be suppressed of the at least two spin species is reduced as much as possible. A phase offset of 180° or x between successive subpulses can also be achieved by way of an alternation of the (complex) amplitudes of the successive subpulses.

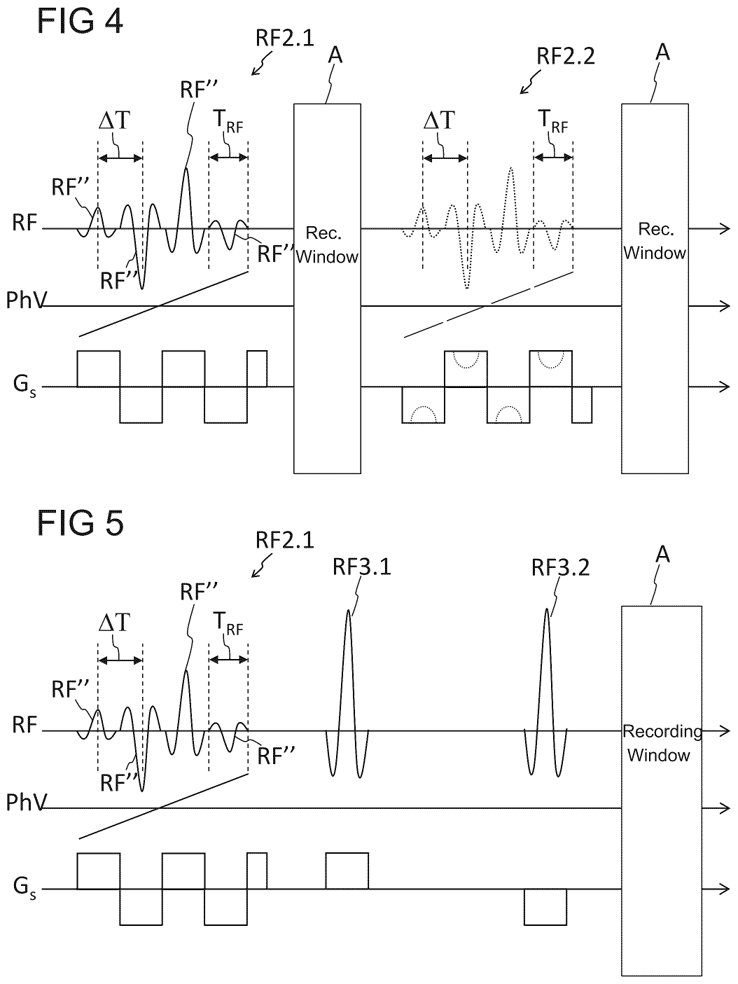

FIG. 4 shows an exemplary, schematic representation of a portion of a pulse sequence scheme for possible composite RF pulses RF2.1, RF2.2 according to the disclosure, each of which can be used, individually or in combination, in a sequence.

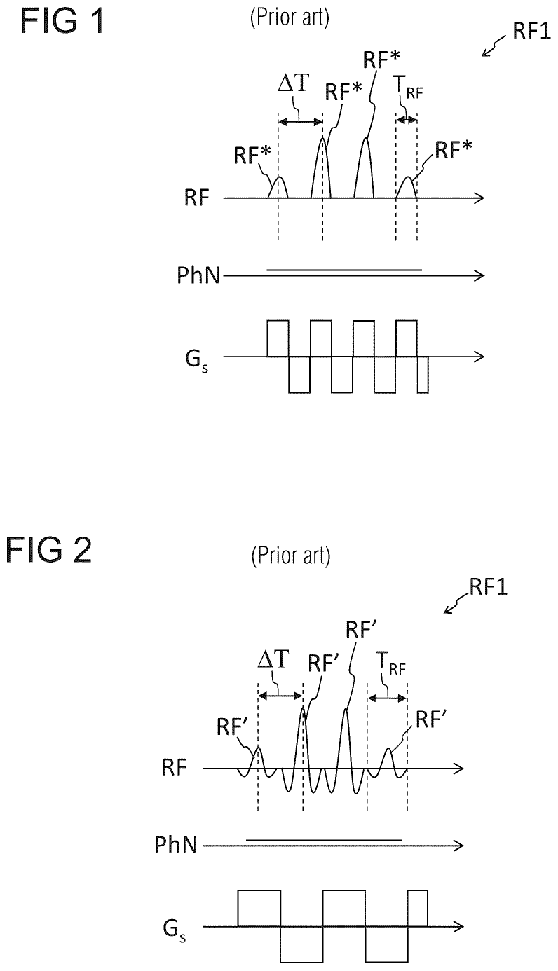

Similarly to FIGS. 1 and 2, RF pulses to be radiated in are shown in the top line RF, and slice selection gradients to be switched (without ramps) are shown in the bottom line G_{S}. The excitation scheme consists herein, for better comparability, in each case either of four successive slice-selecting subpulses RF″ with an amplitude ratio of 1:3:3:1 (the underlines indicate an inverted phase in this example (phase offset of) 180° between the subpulses RF″).

During the radiating in of a composite RF pulse, bipolar slice selection gradients are switched so that successive subpulses of a composite RF pulse are encoded with differently polarized slice selection gradients (block 103). If the composite RF pulse is a binomial pulse, then by way of the switched slice selection gradients, it is a bipolar binomial pulse.

Shown in FIG. 4, by way of example, similarly to FIG. 2, is a bipolar slice selection, wherein during the successive subpulses RF″, a slice selection gradient is switched alternatingly, in each case with different polarity (for example, herein, positive-negative-positive-negative).

The subpulses of a composite RF pulse that is radiated in are radiated at a frequency as the carrier frequency that is detuned by a detuning shift Δf relative to a resonance frequency of a spin species that is to be represented, such that by way of the detuning shift Δf, a linear evolution of the phase over the temporal progression of the composite RF pulse results.

Shown in FIG. 4, by way of example, in the middle line PhV is a possible linear evolution of the phase as generated by the detuning shift according to the disclosure.

By way of radiated-in composite RF pulses, magnetic resonance signals triggered in the examination object are recorded in a recording window A as scan data MD (block 105).

A temporal spacing ΔT between subpulses of the composite RF pulse can be determined dependent upon a chemical shift of two of the at least two different spin species.

As described above, via the temporal spacing ΔT of the subpulses of a composite RF pulse, the spectral selectivity can be determined. For binomial pulses as composite RF pulses from subpulses without a phase offset between the subpulses, for example with a temporal spacing of at least ΔT=π/(γ ΔCS B0) between the subpulses, signal contributions of a spin species chemically shifted by ΔCS can be suppressed, wherein γ is the gyromagnetic ratio and B0 is the strength of the main magnetic field. For example, for B0=3T, γ/2π=42.575 MHz/T and ΔCS=3.3 ppm of a temporal spacing ΔT≈1190 μs.

However, other temporal spacings ΔT are also suitable for this purpose. In particular, the same spectral selectivity can be achieved with a phase difference of π+N*2π, so that a temporal spacing ΔT between subpulses of the composite RF pulse can be determined as the quotient of the sum of the constant pi and a natural multiple N, wherein N can also be zero, but in particular, with N being at least one, twice the value of pi (dividend) and the product of the gyromagnetic ratio with a chemical shift of two of the different spin species Sp1, Sp2 and a strength of a main magnet field of the magnetic resonance system (divisor):

$$Δ T = ( π + N * 2 π ) / ( γ Δ CS B 0 )$$

$$where N = 0 , 1 , 2 , 3 , … , preferably N = 1 , 2 , 3 , …$$

With large selected multiples N, the temporal spacing ΔT of the subpulses becomes larger, so that more time is available for the playing out of the subpulses, so that, for example, an SAR applied by way of the composite RF pulse is lowered and a slice profile can be further improved.

For binomial pulses as composite RF pulses from subpulses with a predetermined phase offset between successive subpulses, with the same condition for the temporal spacing ΔT=π/(γ ΔCS B0) between the subpulses, signal contributions of a spin species chemically shifted by ΔCS of a spin species to be suppressed are obtained. This means that without the detuning according to the disclosure, “on-resonant” spin species (i.e., at their resonance frequency) excited by the composite RF pulse would generate no signal, while a signal from an “off-resonant” spin species remains due to the chemical shift. By way of the detuning shift described here, however, the “on-resonant” condition is again displaced to the spin species that is to be suppressed.

It is therein advantageous that, by way of the constant frequency shift by the detuning shift Δf, the slice profiles of the spin species to be suppressed match slice encoded subpulses with positive and negative polarity so that regardless of the spatial position within the slice manipulated by the composite RF pulse, the desired amplitude ratio, for example, as in FIG. 4, 1-3-3-1 is retained and the signal of the spin species to be suppressed, for example, fat, is indeed suppressed. By way of the detuning shift Δf, the slice profiles of the spin species to be represented, for example, water, are now shifted for subpulses with positive slice selection gradients against those with negative slice selection gradients, which can lead to a slight reduction of the signal of the spin species to be represented. However, this does not usually have a detrimental result. For example, in the case of a water excitation with fat suppression for the image impression and the diagnosis, a slight loss of water signal (i.e. a somewhat lower signal-to-noise ratio (SNR)) is significantly less severe than an also only slight contamination of the image with a residual fat signal, which generates significant image artifacts.

Comparisons, carried out with Bloch simulations, of slice profiles and signal amplitudes of spin species to be represented for unipolar binomial pulses (see FIG. 1), bipolar binomial pulses (see FIG. 2) and RF pulses composited according to the disclosure (see FIG. 4) produce, for the method according to the disclosure, a quality of the achievable slice profiles that is comparable with bipolar binomial pulses, with a significant improvement in the spectral selectivity which is comparable with a quality of the spectral selectivity of unipolar binomial pulses, with only a very slight reduction in the signal obtained.

The detuning shift Δf of the frequency of the subpulses can be selected such that over the temporal progression of the composite RF pulse, it detunes the frequency of the subpulses to a resonance frequency of one spin species of the at least two spin species that is to be suppressed. This can be achieved, for example, in that the detuning shift Δf dependent upon the chemical shift of the spin species that is to be suppressed relative to a spin species that is to be represented of the at least two spin species Sp1, Sp2 is selected according to the following formula:

$$Δ f = ( g DCS B 0 ) / p ,$$

where g is the gyromagnetic ratio, DCS is the chemical shift, B0 is the main magnet field of the magnetic resonance system used and p is the circle constant pi.

The detuning of the frequency of the subpulses by the detuning shift Δf can take place at least at times of an emission of the subpulses (pulse duration TRF) and comprise a switching of an NCO with a frequency constantly shifted by the detuning shift relative to the resonance frequency of a spin species to be represented over the temporal progression of the composite RF pulse. In this way, the frequency is detuned by means of an NCO. In addition or alternatively, the detuning of the frequency can comprise a known frequency and/or phase modulation of the subpulses radiated in, so that the frequency is detuned via the frequency modulation and phase modulation.

The detuning of the frequency of the subpulses by the detuning shift can take place at least at times of an emission of the subpulses, i.e., simultaneously with the radiating in of the subpulses for the respective pulse duration TRF.

The detuning can be effective continuously during the entire composite RF pulse RF2.1.

It is also conceivable that the detuning of the frequency of the subpulses by the detuning shift is generated only during the respective temporal duration of a respective emission of the subpulses, i.e., only at the times at which subpulses are applied (i.e., with interruptions during pause times, for example, during the gradient ramps). During interruptions of this type, care must merely be taken that the start phase of the successive subpulses are each set appropriately so that they each correspond to the phase which would set in with continuous operation of the detuning shift. The line shown interrupted in the row PhV for the right-hand composite RF pulse RF2.2 in FIG. 4 indicating the phase evolution illustrates an effectiveness of the detuning shift only during the subpulses of the composite RF pulse 2.2.

In addition to the detuning shift, the frequency of the subpulses can be detuned by a slice selection shift, as is known in the prior art, in order to manipulate slices S1, S2 at different slice positions without having to switch other gradients. In this way, the method described can be used for the recording of a large number of slices, for example, for the complete mapping of an anatomy relevant for the diagnosis.

The switched bipolar slice selection gradients can be slice selection gradients of a VERSE (variable-rate selective excitation) technique. With VERSE, temporally variable slice selection gradients are used, for example, in order to achieve a reduction of an applied SAR or the RF pulse duration. The indentations, shown dotted, in the slice selection gradients of the right-hand composite RF pulse RF2.2 represent possible progressions of VERSE slice selection gradients. Here also, the evolution of the phase further progresses linearly and is not modulated in dependence upon the variable amplitude of the slice gradients.

In addition, the frequency at which the subpulses are radiated in can be further optimized by means of a slice-specific adjusting method for a respective desired slice, for example, in order to set an optimized middle frequency and/or an optimized amplitude scaling for a desired slice of the imaging (and/or a desired block in three-dimensional imaging) and so to optimize the image quality locally for the current slice. In particular for water excitation-in which the spectral selectivity acts only locally in the slice in contrast to the chemically selective fat suppression-such slice-specific adjustments can lead to significant improvements in the image quality. The displaced middle frequency established by way of the adjustment can be added to the detuning shift that is necessary for the disclosure. Exemplary slice-specific adjustment methods that can be combined with a detuning shift described herein are known, for example, from the publications DE 10 2014 219 778 B4 and (further in combination with a slice multiplexing technique for simultaneous recording of signals from a plurality of slices) DE 10 2015 218 852 A1.

With a composite RF pulse described herein, which is applied together with a bipolar slice selection gradient, it is possible, as described, to configure the duration TRF of the subpulses of the composite RF pulse relatively long, as far as a duration that corresponds to a temporal spacing ΔT between subpulses. Thereby, an SAR applied by way of the composite RF pulse can be reduced. By way of the detuning shift Δf proposed here, at the same time, the quality of the representation of the spin species to be represented is improved so that clinically relevant MR images can be obtained. Particularly with slice multiplexing methods, applied SAR values are often undesirably high due to the simultaneous excitation of a plurality of slices. Here, the composite RF pulses described herein can advantageously counteract this.

In particular, echoplanar diffusion imaging wherein residual signals of non-resonant spin species can lead to pronounced image artifacts, profits from a combination of a composite RF pulse as described herein with slice-specific adjustments. Of decisive importance herein is, firstly, the good suppression of undesirable spin species that is further improved by slice-specific adjustments. Secondly, only the longer duration of the subpulses achievable with the method described herein allows the excitation of thin slices and, thus, recordings of clinically relevant details with high resolution.

A composite RF pulse according to the disclosure can replace a standard RF pulse (not composite) in the most varied of pulse sequence schemes or a known composite RF pulse according to the prior art. According to the desired application, the composite RF pulse can be used as an RF excitation pulse or as a RF refocusing pulse. In principle, a use as an RF inversion pulse or as a so-called store and/or restore RF pulse or (for all types of RF pulses) also an aspect as an asymmetrical RF pulse is conceivable.

Accordingly, a recording technique that is used, with which the scan data MD is recorded, can be a recording technique recording scan data in two-dimensional or three-dimensional space, in particular, a slice multiplexing technique and/or a diffusion recording technique.

The magnetic resonance signals triggered by the composite RF pulse can be generated as gradient echo signals, spin echo signals, turbo spin echo signals, double refocused spin echo signals, and/or stimulated echo signals.

It is conceivable that following a composite RF pulse as described herein, which is an RF excitation pulse, i.e., following a composite RF excitation pulse, at least one first RF refocusing pulse RF3.1 which can be a conventional RF refocusing pulse and at least one second RF refocusing pulse RF3.2 which can also be a conventional RF refocusing pulse, are radiated in. In this way, following a first RF refocusing pulse RF3.1 and a second RF refocusing pulse RF3.2, a double refocused spin echo signal is obtained, and a recording can be made in a respective recording window A. In one aspect of such an at least double refocused spin echo method, during the radiating in of a first RF refocusing pulse, a slice selection gradient with a first polarity can be selected and, during the radiating in of a second RF refocusing pulse, a slice selection gradient with a second polarity can be selected, as shown schematically in FIG. 5, in which the designations for the same items are again selected similarly to FIGS. 1, 2 and 4. In this way, a polarity of slice selection gradients switched during the first RF refocusing pulse is inverted relative to a polarity of slice selection gradients switched during the second RF refocusing pulse, so that similarly to a so-called “gradient reversal” technique, a yet better suppression of a signal to be suppressed of a spin species to be suppressed is achieved.

A phase of at least one subpulse of the composite RF pulse, preferably the respective phase of each subpulse of the composite RF pulse can be manipulated in a known manner in addition to the detuning shift such that a signal phase generated by the composite RF pulse (the phase of the generated transverse magnetization) achieves a desired value. As the desired signal phase, for example, a signal phase achieved with a method known in the prior art which is to be improved by way of the detuning shift described herein, an achieved signal phase can be selected or it can be selected according to an RF spoiling method described, for example, in the article by Zur et al. “Spoiling of Transverse Magnetization in Steady-State Sequences,” Magn. Reson. Med. 21: pp. 251-263, 1991.

The scan data MD recorded is stored and/or further processed (block 107). For example, image data can be reconstructed from recorded scan data MD.

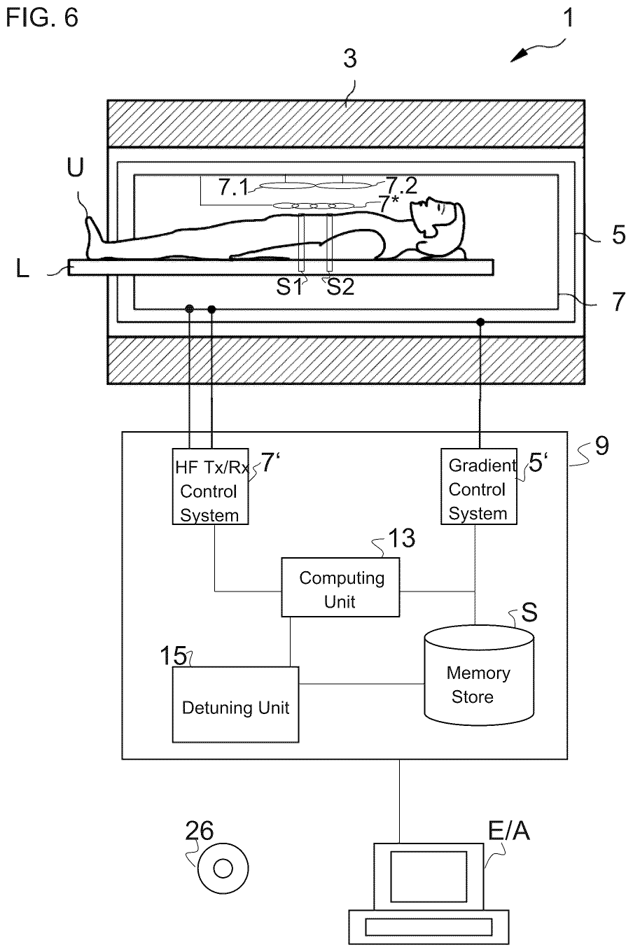

FIG. 6 schematically shows a magnetic resonance system 1 according to the disclosure. This comprises a magnet unit 3 for generating the main magnetic field, a gradient unit 5 for generating the gradient fields, a high frequency unit 7 for radiating in and receiving high frequency signals, and a control facility 9 configured for carrying out a method according to the disclosure.

In FIG. 6, these subunits of the magnetic resonance system 1 are shown only roughly schematically. In particular, the high frequency unit 7 can consist of a plurality of subunits and can comprise, for example, a plurality of coils. In particular, the high frequency unit 7 can comprises a body coil which is permanently integrated into the magnetic resonance system 1 and again can comprise, for example, two antenna elements 7.1 and 7.2. Furthermore, the high frequency unit 7 can comprise one or a plurality of different local coils 7* that can be configured either only for transmitting high frequency signals or only for receiving the triggered high frequency signals or for both, and themselves can comprise a plurality of antenna elements and associated coil channels.

For investigation of an examination object U, for example, a patient or a phantom, it can be introduced on a support L into the magnetic resonance system 1, in the scanning volume thereof. The slices S1 or S2 represent an exemplary target volume of the examination object from which echo signals can be recorded and acquired as scan data.

The control facility 9 serves to control the magnetic resonance system 1 and can, in particular, control the gradient unit 5 by means of a gradient control system 5′ and the high frequency unit 7 by means of a high frequency transmitting/receiving control system 7′. The high frequency unit 7 can herein comprise a plurality of channels on which signals can be transmitted or received.

The high frequency unit 7 is responsible, together with its high frequency transmitting/receiving control system 7′ for the generation and radiating-in (transmission) of a high frequency alternating field for manipulation of the spins in a region to be manipulated (for example, in slices S to be scanned) of the examination object U. Herein, the middle frequency of the high frequency alternating field, also designated the B1 field, is typically adjusted so that, as far as possible, it lies close to the resonance frequency of the spin to be manipulated. Deviations of the middle frequency from the resonance frequency are referred to as off-resonance. In order to generate the B1 field, in the high frequency unit 7, currents controlled by means of the high frequency transmitting/receiving control system 7′ are applied to the RF coils.

Furthermore, the control facility 9 comprises a detuning unit 15 for detuning the frequencies of subpulses of composite RF pulses according to the disclosure. The control facility 9 is configured overall to carry out a method according to the disclosure.

A computing unit 13 included by the control facility 9 is configured to carry out all the computation operations necessary for the required scans and determinations. Intermediate results and results needed for this or established herein can be stored in a memory store S of the control facility 9. The units described are herein not necessarily to be understood as physically separate units, but merely represent a subdivision into units of purpose which, however, can also be realized, for example, in fewer, or even only in one single, physical unit.

Via an input/output facility E/A of the magnetic resonance system 1, for example, control commands can be passed, for example, by a user to the magnetic resonance system and/or results from the control facility 9 such as, for example, image data can be displayed.

A method described herein can also exist in the form of a computer program which comprises commands which carry out the described method on a control facility 9. Similarly, a computer-readable storage medium can be provided that comprises commands that, when executed by a control facility 9 of a magnetic resonance system 1, cause it to carry out the method described.

Independent of the grammatical term usage, individuals with male, female, or other gender identities are included within the term.

1. A method for recording scan data of an examination object, which comprises spins of at least two different spin species, using a magnetic resonance system, the method comprising:
radiating in a composite radio frequency (RF) pulse that is a binomial pulse comprising at least two subpulses with a predetermined phase offset between successive subpulses;
switching bipolar slice selection gradients so that successive subpulses of the composite RF pulse are encoded with differently polarized slice selection gradients;
recording as scan data magnetic resonance signals triggered by the composite RF pulse; and
storing and/or further processing the recorded scan data,
wherein the subpulses are radiated in at a frequency that is detuned by a detuning shift relative to a resonance frequency of a spin species that is to be represented, such that by way of the detuning shift, a linear evolution of the phase over a temporal progression of the composite RF pulse results.

2. The method as claimed in claim 1, wherein a temporal spacing between subpulses of the composite RF pulses are determinable dependent upon a chemical shift of two of the at least two different spin species.

3. The method as claimed in claim 1, wherein the detuning shift detunes the frequency of the subpulses over the temporal progression of the composite RF pulse to a resonance frequency of one spin species of the at least two spin species that is to be suppressed and/or the predetermined phase offset is a phase offset of 180°.

4. The method as claimed in claim 1, wherein the detuning of the frequency of the subpulses by the detuning shift at least at times of an emission of the subpulses comprises a switching of a numerically controlled oscillator (NCO) with a frequency constantly shifted by the detuning shift over the temporal progression of the composite RF pulse and/or a frequency and/or phase modulation of the radiated-in subpulse.

5. The method as claimed in claim 1, wherein the detuning of the frequency of the subpulses by the detuning shift is generated only during the respective temporal duration of a respective emission of the subpulses.

6. The method as claimed in claim 1, wherein the frequency of the subpulses is detuned in addition to the detuning shift by a slice selection shift.

7. The method as claimed in claim 1, wherein the switched bipolar slice selection gradients are slice selection gradients of a VERSE (variable-rate selective excitation) technique.

8. The method as claimed in claim 1, wherein the frequency with which the subpulses are radiated in is further optimized using a slice-specific adjusting method for a respective desired slice.

9. The method as claimed in claim 1, wherein the composite RF pulse is an RF excitation pulse or an RF refocusing pulse, an RF inversion pulse, a store, and/or restore RF pulse which is configured symmetrical or asymmetrical.

10. The method as claimed in claim 1, wherein the scan data is recorded using a recording technique recording scan data in two-dimensional or three-dimensional space.

11. The method as claimed in claim 1, wherein the magnetic resonance signals triggered by the composite RF pulse are generated as gradient echo signals, spin echo signals, turbo spin echo signals, double refocused spin echo signals and/or stimulated echo signals.

12. The method as claimed in claim 1, wherein following a composite RF pulse radiated in as an RF excitation pulse, at least one first RF refocusing pulse and at least one second RF refocusing pulse are radiated in such that, following a first RF refocusing pulse and a second RF refocusing pulse, a double refocused spin echo signal is generated, wherein a polarity of slice selection gradients switched during a first RF refocusing pulse is opposite to a polarity of slice selection gradients switched during a second RF refocusing pulse.

13. The method as claimed in claim 1, wherein a phase of at least one subpulse of the composite RF pulse is manipulated such that a signal phase generated by the composite RF pulse achieves a desired value.

14. The method as claimed in claim 1, wherein the at least two different spin species are spin species from a group spin species consisting of water, fat, and silicone.

15. A magnetic resonance system, comprising:
a magnet unit;
a gradient unit;
a high-frequency unit; and
a control facility with a high-frequency transmitting/receiving control system and with a detuning unit,
wherein the control facility is configured to carry out a method as claimed in claim 1 on the magnetic resonance system.

16. A non-transitory computer-readable storage medium comprising commands which, on execution by a control facility of a magnetic resonance system, cause the magnetic resonance system to carry out the method as claimed in claim 1.
